(19) United States
(12) Patent Application Publication
(10) Pub. No.: US 2025/0137841 A1
(43) Pub. Date: May 1, 2025

(54) OPTICAL SENSOR MODULE

(71) Applicant: STMicroelectronics International N.V., Geneva (CH)

(72) Inventors: William HALLIDAY, Edinburgh (GB); Brandon Scott JOHNSON, Edinburgh (GB); Fraser WILLIAMS, Edinburgh (GB); Garrie VICKERS, Edinburgh (GB); Andrew John PRICE, Bonnyrigg (GB); Axel CROCHERIE, Edinburgh (GB); Yandong MAO, Shanghai (CN); Fabrice MARTIN, Saint Egrève (FR); Tat Ming TEO, Singapore (SG); Vincent BEIX, Chambéry (FR); Justin CATANIA, Grenoble (FR)

(21) Appl. No.: 18/926,250

(22) Filed: Oct. 24, 2024

Related U.S. Application Data
(63) Continuation-in-part of application No. 18/417,190, filed on Jan. 19, 2024.
(63) Continuation-in-part of application No. 18/432,693, filed on Feb. 5, 2024.
(63) Continuation-in-part of application No. 18/746,712, filed on Jun. 18, 2024.

(30) Foreign Application Priority Data
Oct. 25, 2023 (FR) 2311572
Oct. 25, 2023 (FR) 2311593

(51) Int. Cl. G01J 1/02; G01J 1/04; G01J 1/44

(52) U.S. Cl. CPC G01J 1/0271; G01J 1/0411; G01J 1/44; G01J 2001/0276

(57) ABSTRACT

Example embodiments of the present disclosure provide an optical module sensor. An example optical module sensor may include an optical radiation-emitting device, a reference, an optical radiation receiver positioned, an electromagnetic interference shield, and a housing cap. The housing cap may include a barrier wall positioned such that the housing cap defines a transmission cavity and a receiving cavity. The optical radiation-emitting device and the reference sensor may be positioned within the transmission cavity and the optical radiation receiver may be positioned within the receiving cavity. The housing cap may include an attenuation wall positioned between the reference sensor and the optical radiation receiver.

### CROSS REFERENCE TO RELATED APPLICATIONS

This application is a continuation-in-part of U.S. patent application Ser. No. 18/417,190 filed on Jan. 19, 2024, and a continuation-in-part of U.S. patent application Ser. No. 18/432,693 filed on Feb. 5, 2024, and a continuation-in-part of U.S. patent application Ser. No. 18/746,712 filed on Jun. 18, 2024, and claims the benefit and priority to French Patent Application No. 2311572 filed on Oct. 25, 2023, and French Patent Application No. 2311593 filed on Oct. 25, 2023, the contents of each of which is incorporated by reference herein in their entirety.

### FIELD OF THE INVENTION

Example embodiments of the present disclosure relate generally to optical sensors, and, more particularly, to optical sensor modules such as a three dimensional (3D) depth sensor module.

### BACKGROUND

Various example embodiments address technical problems associated with optical noise from unwanted sources in an optical sensor, for example, an optical ranging sensor, a proximity, a 3D depth sensor, or an image sensor. During operation of an optical sensor, optical radiation may be received from various unwanted sources. Such optical radiation from unwanted sources, cause and/or increase optical noise in various internal components of the optical sensor and reduces the signal-to-noise ratio (SNR) of the reflections off the target object, which in turn, lead to inaccurate and/or inconsistent readings from an optical sensor. In particular, 3D depth sensors such as time-of-flight (ToF) sensors often experience crosstalk between internal components of the 3D depth sensor.

Further optical sensors benefit from electromagnetic interference (EMI) shielding to reduce the adverse effects of EMI on the operation of the optical sensor. Conventional sensors employing an external EMI shield are often vulnerable to damage during handling, shipping, and/or the like.

Further, the compact form factor for electronic devices, and particularly mobile devices including optical sensors, pose challenges as space within the device for various components is limited. This package arrangement results in complex assembly techniques that require accurate and repeatable handling. Components that are vulnerable to damage can be compromised during the handling process and may thus be a point of failure for the electronic device.

Applicant has identified many technical challenges and difficulties associated with optical sensors, including reducing the optical noise received at internal components of an optical sensor, EMI shielding, and optical sensor module packaging. Through applied effort, ingenuity, and innovation, Applicant has solved problems related to the receipt of optical noise in an optical sensor, EMI shielding, and optical sensor module packaging by developing solutions embodied in the present disclosure, which are described in detail below.

### BRIEF SUMMARY

Various embodiments described herein relate optical sensors having cross talk mitigating features.

In accordance with various embodiments of the present disclosure, an optical sensor module is provided. The optical sensor module comprising an optical radiation-emitting device configured to generate optical radiation directed at a target object; a reference sensor positioned to receive a portion of the optical radiation; an optical radiation receiver positioned to receive reflected optical radiation reflected off the target object; an electromagnetic interference shield defining an interior, wherein the optical radiation-emitting device is positioned within the interior, and wherein the electromagnetic interference shield comprises a top surface defining an aperture positioned such that the optical radiation generated by the optical radiation-emitting device passes through the aperture; and a housing cap comprising a barrier wall positioned such that the housing cap defines a transmission cavity and a receiving cavity, wherein the optical radiation-emitting device and the reference sensor are positioned within the transmission cavity, and wherein the optical radiation receiver is positioned within the receiving cavity; and an attenuation wall positioned between the reference sensor and the optical radiation receiver.

In some embodiments, the barrier wall creates an impenetrable barrier between the transmission cavity and the receiving cavity.

In some embodiments, the attenuation wall is positioned over the electromagnetic interference shield such that the attenuation wall and the electromagnetic interference shield define an attenuation gap through which the portion of the optical radiation passes to the reference sensor.

In some embodiments, the example optical sensor module further comprises an integrated circuit device, wherein the integrated circuit device comprises the optical radiation receiver and the reference sensor, and wherein a distal end of the barrier wall is attached to the integrated circuit device.

In some embodiments, the example optical sensor module further comprises a receiver lens positioned within the receiving cavity and above the optical radiation receiver.

In some embodiments, the example optical sensor module further comprises a receiver filter positioned within the receiving cavity and above the receiver lens.

In some embodiments, the example optical sensor module further comprises a substrate, wherein the optical radiation-emitting device, the reference sensor, the optical radiation receiver, and the electromagnetic interference shield are disposed on the substrate and electrically connected to the substrate.

In some embodiments, the example optical sensor module further comprises at least one conductive pad disposed on the substrate and electrically connected to ground, wherein the electromagnetic interference shield is electrically connected to the substrate via the at least one conductive pad.

In some embodiments, the example optical sensor module further comprises a transmission lens positioned relative to the optical radiation-emitting device such that the optical radiation generated by the optical radiation-emitting device passes through the transmission lens. In some embodiments, the transmission lens comprises a conductive trace.

In some embodiments, the example optical sensor module further comprises at least one conductive lead frame positioned within the interior of the housing cap and electrically connected to the substrate; and at least one conductive wire formed by wire bonding, the at least one conductive wire electrically connecting the at least one conductive lead frame to the conductive trace.

In some embodiments, the electromagnetic interference shield comprises a metal can.

In some embodiments, the housing cap further comprises a top portion defining a transmission opening positioned over the optical radiation-emitting device such that the optical radiation generated by the optical radiation-emitting device passes through the transmission opening to the target object.

In some embodiments, the top portion of the housing cap further defines a receiving opening positioned over the optical radiation receiver, such that the reflected optical radiation passes through the transmission opening to the optical radiation receiver.

In some embodiments, the top portion and the attenuation wall comprise a single, continuous structure.

In some embodiments, the top portion and the barrier wall comprise a single, continuous structure.

In some embodiments, the optical radiation-emitting device comprises at least one optical radiation source.

In some embodiments, the optical radiation receiver comprises a first single photon avalanche diode and the reference sensor comprises a second single photon avalanche diode.

In some embodiments, the top surface of the electromagnetic interference shield comprises an inner angled surface surrounding the aperture.

In some embodiments, the example optical sensor module further comprises a driver configured for controlling the optical radiation-emitting device; and a photodiode configured to monitor the optical radiation-emitting device, wherein the driver and the photodiode are positioned within the interior defined by the electromagnetic interference shield.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

Reference will now be made to the accompanying drawings. The components illustrated in the figures may or may not be present in certain embodiments described herein. Some embodiments may include fewer (or more components) than those shown in the figures in accordance with an example embodiment of the present disclosure.

FIG. 1 depicts a top view of a portion of an example optical sensor module in accordance with an example embodiment of the present disclosure.

FIG. 2 depicts a perspective view of a portion of an example optical sensor module in accordance with an example embodiment of the present disclosure.

FIG. 3 depicts a cross section view of an optical sensor module in accordance with an example embodiment of the present disclosure.

FIG. 4 depicts emission plots comparing emissions of an optical sensor module having an EMI shield in accordance with an example embodiment of the present disclosure with an optical sensor module without an EMI shield.

### DETAILED DESCRIPTION OF THE INVENTION

Example embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

The use of the term “circuitry” as used herein with respect to components of a system or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communications circuitry, input/output circuitry, and the like. In some embodiments, other elements may provide or supplement the functionality of particular circuitry.

The terms “optical sensor module,” “optical module,” and “optical sensor” are used herein interchangeably to refer to, without being limited to, a proximity sensor module, a time-of-flight (ToF) module, an ambient light sensor (ALS) module, a 3D Lidar module, and/or a camera module. The term optical sensor module also includes an optical sensor module with combined functions, for example a combination of at least two of the above-mentioned modules, or other functions.

The terms “time-of-flight sensor,” “time-of-flight module,” “3D optical sensor,” and 3D optical sensor module refer to an optical sensor module having a range imaging camera for measuring distances between the camera and a target object based on the round-trip time of optical radiation (e.g., light signal), such as may be provided by one or more optical radiation sources (e.g., one or more light sources). The one or more optical radiation sources may comprise one or more vertical-cavity surface-emitting lasers (VCSELs). As non-limiting examples, time-of-flight (ToF) sensors may be used in mobile devices, such as smartphones, to provides features such as camera autofocus and facial recognition.

### Overview

Various example embodiments address technical problems associated with receiving optical noise at an optical radiation receiver and reference sensor of an optical sensor (e.g., optical ranging sensor, optical proximity sensor, optical image sensor, and/or the like).

Optical sensors, such as 3D sensors, TOF sensors, and/or the like, may be used to detect the presence of nearby objects. Optical sensors are able to do so without physically touching the object. Some types of optical sensors, such as those utilized in optical ranging devices, 3D sensors, TOF sensors, and/or the like, may be used to determine the actual distance to such nearby objects. Optical sensors may be utilized in various electronic devices, such as cameras, phones, including smartphones, smartwatches, tablets, vehicles, machinery, and other devices for detecting the presence of and/or distance to nearby objects.

As understood by those of skill in the field to which the present disclosure pertains, there are numerous example scenarios in which the accuracy and consistency of an optical sensor may be improved by reducing crosstalk in optical sensors. In particular, the accuracy of an optical sensor may be improved by reducing the amount of optical noise received at the optical radiation receiver and/or the reference sensor.

Crosstalk optical radiation is any optical radiation received at the optical radiation receiver of the optical sensor module that was not transmitted by the optical radiation-emitting device of the optical sensor module, or that did not take a direct path from the optical radiation-emitting device to the target object and return to the optical radiation receiver. Crosstalk optical radiation may emanate from the optical radiation-emitting device and pass through a transmission filter. A portion of the optical radiation may be refracted of the optical transmission axis and directed into the external cover of the optical sensor module at an incident angle such that the optical radiation is internally reflected within the external cover. The optical radiation may then be received directedly by the optical radiation receiver without encountering the target object. Such path of crosstalk optical radiation may be a major source of optical noise at the optical radiation receiver.

During operation of an optical sensor, optical radiation is transmitted by an optical radiation-emitting device. The optical radiation may be directed through one or more transmitting optical structures, display screens, cover glass, and/or lens toward a target object. The transmitted optical radiation may interact with the target object, reflecting a portion of the transmitted optical radiation toward an optical radiation receiver of the optical sensor module. In addition, a portion of the transmitted optical radiation may be directed internally toward a reference sensor. The reference sensor may be configured to produce a reference signal for comparison with the reflected portion of the transmitted optical radiation. Based on the comparison of the reflected portion of the transmitted optical radiation returned from the target object and the reference signal from the reference sensor, an optical sensor may determine certain characteristics related to the proximity of the target object, for example, the distance of the target object, position of the target object, motion of the target object, and/or the speed of the target object.

In addition to the portion of transmitted optical radiation reflected toward an optical radiation receiver and portion of the transmitted optical radiation directed internally toward the reference sensor, optical noise from unwanted sources, such as ambient light in the operating environment of the optical sensor module, may be received by the optical radiation receiver and/or the reference sensor. Optical noise from unwanted sources, such as but not limited to reflections off various surfaces of the optical sensor module (e.g., including an external cover thereof), and/or optical radiation from ambient source, increases the optical noise received at the optical radiation receiver and may diminish the reflected optical radiation from the target object and the reference signal generated by the reference sensor. For example, optical noise received from ambient light may enter in through the transmission opening of the optical sensor module and interact with the reference sensor, and as a result diminish the reference signal generated by the reference sensor.

Such an increase in unwanted optical noise at the optical radiation receiver and increase in unwanted optical noise at the reference sensor equates to a reduction in the SNR of the reflection of the target object. As the SNR is reduced due to unwanted optical noise, the output from the optical sensor becomes increasingly inaccurate and inconsistent.

Previous attempts to mitigate the receipt of optical noise at the reference sensor have included placing optical filters over the transmission opening and selection of housing materials. Optical filters allow the transmitted light to escape but prevent optical noise from entering the optical sensor. However, optical filters on the transmission opening add to the overall cost of the optical sensor. In addition, positioning the optical filters on the transmission opening may increase the complexity of manufacturing optical sensor modules. Further, the glue used to attach optical filters may crack and give way over time, causing the optical filter to dislodge or displace during operation.

Further, an optical sensor manufacturer may select materials to absorb one or more wavelengths of light. However, such materials often have material limitations with respect to the characteristics of the cap of the optical sensor module. In addition, an optical sensor manufacturer may select materials and/or a surface that randomly diffuses any incident light. Such an option may randomly reflect light towards the optical radiation receiver, increasing crosstalk optical radiation, among other things.

Further, reducing noise from unwanted crosstalk may be further complicated by system integration requirements. For example, many electronic systems may have strict size requirements, such that an optical sensor may be placed within an electronic device or under an external cover. Such system integration requirements prevent solutions that increase the size of the optical sensor module. The compact form factor for mobile devices poses a challenge as space within the device for various components is limited. The various components of the electronic device (e.g., sensors, display(s), cameras, communications interface, speakers, and/or the like) all compete for space within a chassis that needs to be both small and durable in many applications. The compact form factor, required to achieve the various functionalities of a device and their respective sizes lead to intricate packaging within the device with close-coupled components. This package arrangement results in complex assembly techniques that require accurate and repeatable handling. Components that are vulnerable to damage can be compromised during the handling process and may thus be a point of failure for the mobile device.

Further an optical sensor benefits from electromagnetic interference (EMI) shielding to reduce the adverse effects of EMI on the operation of the optical sensor. EMI mitigation and/or reduction is a key design parameter in optical sensor design. Conventional sensors employing an external EMI shield are often vulnerable to damage during handling, shipping, and/or the like.

With the demand for highly accurate optical sensor modules increasing, there is a need to reduce the amount of optical noise received at the optical radiation receiver and the reference sensor of optical sensors, while subsequently reducing cost, simplifying manufacturing, and increasing reliability.

Various example embodiments described herein utilize various techniques to reduce or eliminate crosstalk, including the reception of optical noise at the optical radiation receiver and reference sensor of an optical sensor. For example, various example embodiments described herein utilize various crosstalk reducing features of the housing cap to reduce unwanted optical noise received at the optical radiation receiver and the reference sensor of an optical sensor. By utilizing crosstalk reducing features of a housing cap of an optical sensor module, the amount of unwanted optical noise received at the optical radiation receiver and the reference sensor may be substantially reduced. Reduction in the unwanted optical noise at the optical radiation receiver and reference sensor may improve the performance and overall consistency of the optical sensor module. Accordingly, as a result of the herein described example embodiments and in some examples, the effectiveness of optical ranging sensors, optical proximity sensors, optical image sensors, and other optical sensors may be greatly improved.

In various embodiments, the optical sensor module includes a barrier wall dividing the optical sensor module into a transmission cavity and a receiving cavity, and that functions as an optical isolator for substantially preventing the internal propagation of optical radiation between the optical radiation-emitting device of an optical sensor module and the optical radiation receiver of the optical sensor module.

Additionally, in various embodiments, an attenuation wall is placed in the transmission cavity of the optical sensor module between the optical radiation-emitting device and the reference sensor of the optical sensor module. The attenuation wall prevents optical noise, such as ambient light from the operating environment, entering the transmission cavity of the optical sensor module from interacting with the reference sensor. In addition, the attenuation wall defines an attenuation gap between a distal end of the attenuation and a substrate surface or internal structure of the optical sensor module to enable transmission of a portion of the transmitted optical radiation to the reference sensor, while blocking optical noise from reaching the reference sensor.

Additionally, in various embodiments, an EMI shield configured to shield EMI sensitive components of the optical sensor module is positioned within the transmission cavity of the optical sensor module. The EMI shield is dimensioned and positioned such that it at least partially surrounds such EMI sensitive components to mitigate against EMI. Further, the EMI shield defines an aperture configured to provide optical radiation path from the optical radiation-emitting device of the optical sensor module to allow optical radiation to pass through without obstruction while shielding EMI from passing through. In particular, in some embodiments, the EMI shield defines an aperture having an optimal size that is large enough to allow optical radiation to pass through without obstruction and small enough to prevent EMI from passing through. In various embodiments, the EMI shield is connected to a substrate of the optical sensor module via, for example, solder pads that are connected to a ground for the optical sensor module, which increases the effectiveness of the EMI shield. In some embodiments, such solder pads may be at least one of conductive pads 101. Further, the EMI shield may reduce the amount of crosstalk between the transmission cavity and receiving cavity of the optical sensor module.

In various embodiments, the optical radiation-emitting device of an optical sensor module is covered by a glass, such as an optical lens, for protecting the optical radiation-emitting device, for example, from dust. In various embodiments, the glass (e.g., optical lens) is relatively transparent to light at the wavelengths used, covers the transmission opening of the optical sensor module, and also functions as a diffuser suitable for reducing to some extent the intensity of the emitted optical radiation, for example for safety reasons, such as protecting a user. In various embodiments, the housing cap of the optical sensor module is assembled with the optical lens at the transmission cavity of the optical sensor module.

In various embodiments, the glass (e.g., optical lens) is embedded with or otherwise includes at least one conductive trace, such as copper traces (e.g., thin copper traces), that allow optical radiation to pass through. In various embodiments, the conductive trace(s) are electrically connected to lead frame(s) of the optical sensor module via wire bond. For example, the end of the lead frame may have wire bonded connecting itself to the ends of the conductive traces in the optical lens.

As a result of the herein described example embodiments and in some examples, the accuracy and reliability of an optical sensor may be greatly improved. In addition, the cost and complexity required for manufacturing optical sensors may be greatly reduced. For example, the barrier wall reduces the amount of optical noise received at the optical radiation receiver of an optical sensor and the attenuation wall reduces the amount of optical noise received at the reference sensor of an optical sensor. A reduction of optical noise at the reference sensor, for example enables an accurate reference signal based on the transmitted optical radiation to be generated. An accurate reference signal produces more accurate distance and motion data when compared with the ranging optical radiation reflected off a target. In addition, the attenuation wall eliminates the need for optical filters placed over the transmission opening of the optical sensor module. Optical filters add to the overall cost of the optical sensor due to the cost of the optical filter and the additional manufacturing complexity of installing an optical filter. In addition, the techniques for attaching the optical filter may fail. For example, the glue used to attach some optical filters may crack, allowing the optical filter to become detached. Once the optical filter has detached, the accuracy of the optical sensor module may be compromised.

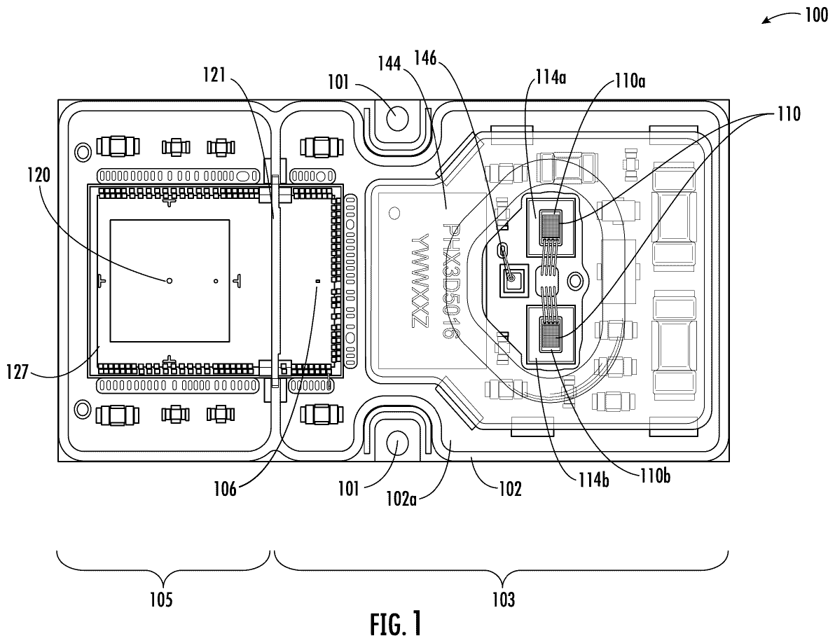

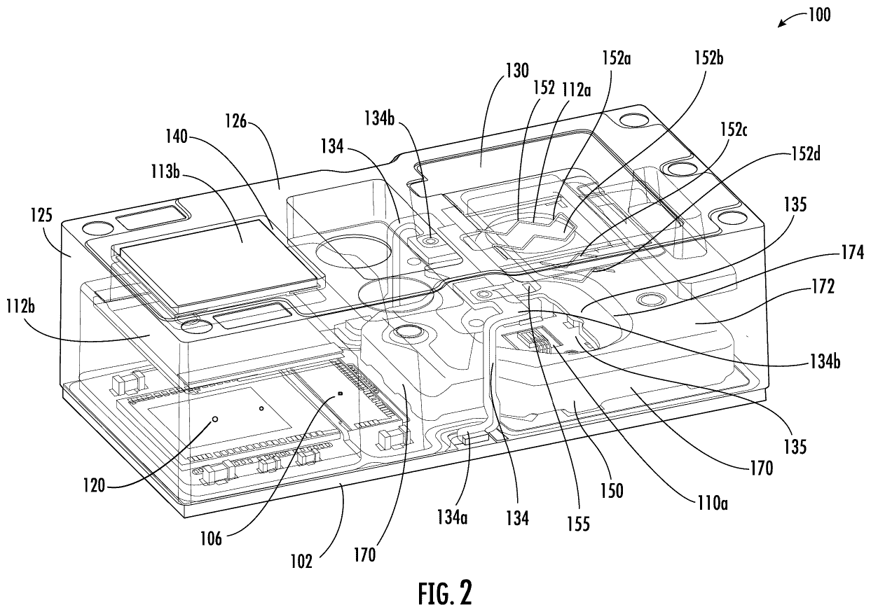

FIG. 1 depicts a top view of a portion of an example optical sensor module 100 and FIG. 2 depicts a perspective view of a portion of the example optical sensor module 100 in accordance with an example embodiment of the present disclosure. In particular, FIG. 1, depicts a top view of example optical sensor module 100 shown without at least a housing cap thereof and FIG. 2 depicts a perspective view of the example optical sensor module 100 shown without at least a barrier wall and attenuation wall thereof.

The optical sensor module 100 may be installed in, for example, a mobile device such as a mobile phone or other electronic devices. The optical sensor module 100 includes an optical radiation-emitting device 110, a reference sensor 106, and an optical radiation receiver 120 electrically connected to a substrate 102.

The substrate 102 is any structure configured to support the attachment of the components of the optical sensor module 100 including the optical radiation-emitting device 110, the optical radiation receiver 120, the reference sensor, and a housing cap 125 (described further below). In some embodiments, the substrate 102 may comprise a printed circuit board (PCB) or ceramic alumina including electrical connections connecting the components of the optical sensor module 100 to a processor, controller, analog-to-digital converter, and/or other electrical components. The optical radiation-emitting device 110, the reference sensor 106, and the optical radiation receiver 120, may be electrically coupled to and/or via the substrate 102.

The optical radiation-emitting device 110 is any optical radiation source, such as a laser diode, a light-emitting diode, bulb, semiconductor device, or other photon-emitting structure configured to generate optical radiation. In some embodiments, an optical radiation-emitting device 110 may comprise a semiconductor laser diode, for example, a vertical cavity surface emitting laser (VCSEL) and/or an edge emitting laser diode. In some embodiments, and as depicted in FIG. 1, the optical sensor module 100 includes an optical radiation-emitting device 110 comprising two optical radiation sources 110a, 110b (e.g., two light sources). In various embodiments, each of the optical radiation sources 110a, 110b comprise a VSCELs. In general, an optical radiation-emitting device 110 may output a coherent light beam upon receipt of a current.

As described above, the optical radiation-emitting device 110 in FIG. 1 comprises a first optical radiation source 110a and a second optical radiation source 110b. The first optical radiation source 110a and the second optical radiation source 110b are disposed on a substrate 102. In some embodiments, the first optical radiation source 110a is mounted on a first interposer 114a and the second optical radiation source 110b is mounted on a second interposer 114b, the first and second interposers 113a, 113b being mounted on a top surface 102a of the substrate 102. In some embodiments, the first optical radiation source 110a and the second optical radiation source 110b may be mounted on the substrate 102 without interposers. In some embodiments, the optical radiation-emitting device 110 may comprise only one optical radiation source or more than two optical radiation sources.

The top surface 102a of the substrate 102 includes conductive pads 101 which are for example at, or close to, edges of the substrate 102. For example, the substrate 102 may include circuitry comprising at least one conductive pads. In some embodiments, the at least one conductive pad is electrically connected to ground. The optical sensor module 100 comprises a driver, such as a laser driver 144, configured for controlling the first and second optical radiation sources 110a, 110b (e.g., VSCELS). In addition, the optical sensor module 100 may include a photodiode 146 configured to monitor the optical radiation-emitting device. In various embodiments, the laser driver 144 and the photodiode 146 are each located in the same cavity (e.g., transmission cavity as further described below) as the optical radiation-emitting device 110.

The optical radiation-emitting device 110 may be configured to output optical radiation (e.g., light signal(s)). Optical radiation is any optical signal transmitted by an optical radiation-emitting device toward a target object to determine characteristics related to the position and/or motion of the target object. In some embodiments, the optical radiation may be a pulsed laser signal. For example, the optical radiation-emitting device may be configured to generate uniform laser pulses. Utilizing a pulsed laser signal may enable a controller to determine the time of flight of the optical radiation once the reflected optical radiation is received at an optical radiation receiver. In some embodiments, the optical radiation may be a continuous wave laser signal. In such embodiments, the continuous wave laser signal may enable a controller to determine proximity of a target object by correlating the proximity of the target object with the phase change in the optical radiation as it is emitted by the optical radiation-emitting device, reflected off the target object, and subsequently received by the optical radiation receiver. Characteristics related to the position and/or motion of target objects may include the distance of the target object from the optical sensor, the position of the target object, the speed of the target object, the direction of motion of the target object, and other similar characteristics related to the position of the target object in the operating environment.

In some embodiments, the optical radiation-emitting device 110 is configured to emit optical radiation at a particular frequency or frequency range, and the optical radiation receiver 120 is adapted to detect the emitted optical radiation in return, for example reflected by the target object. In one embodiment, the optical radiation-emitting device 110 is configured to cmit infrared (IR) light signals, and the optical radiation receiver 120 is adapted to detect the IR light signals in return, for example reflected by the target object.

As described above, in various embodiments, the optical radiation transmitted by the optical radiation-emitting device 110 is directed at a target object. A target object is any object, structure, person, entity, or other item positioned in the line-of-sight of the optical radiation transmitted by the optical sensor module 100. In some embodiments, the optical sensor module 100 may be configured to determine one or more proximity characteristics of the target object, such as the spatial position, composition, proximity, motion, and/or speed of the target object. For example, in some embodiments, the optical sensor module 100 may be positioned under the electronic display screen of a mobile device (e.g., external cover) and may be configured to detect a target object within a pre-determined threshold distance of the optical sensor module 100. In some embodiments, in an instance in which a target object is within the pre-determined threshold distance of the optical sensor module 100, the mobile device may deactivate the touch screen, turn off the display, or take any other relevant action.

A certain portion of the optical radiation may reflect off the target object as reflected optical radiation. Reflected optical radiation is any portion of the optical radiation transmitted by the optical radiation-emitting device 110 of the optical sensor module 100 that is reflected off the target object and received by the optical radiation receiver 120 of the optical sensor module 100. The reflected optical radiation is used to determine the proximity characteristics of the target object.

In various embodiments, the optical sensor module 100 includes an optical radiation receiver 120. The optical radiation receiver 120 is any set of one or more photodiodes, integrated circuits, sensors, light sensing diodes, or other structures that produce an electric signal as a result of light received at the optical radiation receiver 120. The electric current output from the optical radiation receiver 120 may be used to determine the intensity or amplitude of the optical radiation striking or otherwise incident on the optical radiation receiver 120. In some embodiments, the optical radiation receiver 120 may be a light sensitive semiconductor diode that creates an electron-hole pair at the p-n junction when a photon of sufficient energy strikes the optical radiation receiver 120. In various embodiments, and as depicted in FIG. 1, the optical radiation receiver 120 comprises a photodiode such as single photon avalanche diode (SPAD). In some embodiments, the optical radiation receiver 120 may comprise a plurality of photodiodes.

In some embodiments, the optical sensor module 100 may include a processing device electrically connected to the optical radiation receiver 120 and configured for processing signals received from the optical radiation receiver 120. The processing device may be configured to receive the electrical signal generated by the optical radiation receiver 120 representing the intensity or other properties of optical radiation received at the optical radiation receiver 120 and the electrical signal generated by the reference sensor 106. In some embodiments, the processing device may be configured to determine a time-of-flight of the optical radiation (transmitted by the optical radiation-emitting device 110 based on the electrical signal received by the optical radiation receiver 120) and/or a change in phase of the optical radiation and determine one or more characteristics related to the physical position of the target object. The reception of crosstalk optical noise at the optical radiation receiver 120 may diminish the accuracy of an optical sensor.

In various embodiments, the optical sensor module 100 includes a reference sensor 106. The reference sensor 106 is any light-sensitive sensor configured to produce a reference signal based on a portion of optical radiation received from the optical radiation-emitting device 110. During operation of an optical sensor module 100, the optical radiation-emitting device 110 transmits optical radiation toward a target object. A portion of the optical radiation is directed toward the reference sensor 106. Thus, the received portion of the optical radiation may be compared to the reflected optical radiation reflected off the target object. A reference sensor 106, for example, may generate a reference signal for comparison to the electrical signal generated by the optical radiation receiver 120. By comparing the reference signal produced by the reference sensor 106 with the electrical signal produced by the optical radiation receiver 120, physical properties of the target object, including physical properties related to the position and motion of the target object may be determined. For example, more accurate measurements of the reflected optical radiation may be determined.

In various embodiments, and as depicted in FIG. 1, the reference sensor 106 comprises a photodiode such as single photon avalanche diode (SPAD). In this regard, in some embodiments, the optical sensor module 100 includes an optical radiation receiver 120 comprising a first SPAD and a reference sensor 106 comprising a second SPAD. In some embodiments, the reference sensor 106 may comprise a plurality of photodiodes.

In various embodiments, the optical radiation receiver 120 and the reference sensor 106 are embodied by an integrated circuit device 127 (also referred to herein as IC device or IC detector) mounted on the top surface 102a of the substrate 102. The IC device 127 (e.g., thus, the optical radiation receiver 120 and the reference sensor 106 thereof) may be coupled to the substrate 102 using conductive connectors, for example conductive wires, and/or may be secured to the substrate 102, such as by an adhesive material and/or a solder. The adhesive material may be any material suitable for securing the IC device to the substrate, such as tape, paste, gluc.

The optical sensor module 100 may include other electrical circuits or components, which may be mounted on the top surface 102a of the substrate 102. In some embodiments, such other electrical circuits or components may include resistors, capacitors, and/or the like.

As depicted in FIG. 2. The optical sensor module 100 includes a housing cap 125. The optical radiation-emitting device 110, the optical radiation receiver 120, and the reference sensor 106 may be disposed on the substrate 102 and the housing cap 125 may be attached to the substrate 102 over the optical radiation-emitting device 110, the optical radiation receiver 120, and the reference sensor 106, thereby forming the optical sensor module (also referred to herein as optical sensor package).

The housing cap 125 is any package, cover, container, or other covering configured to protect the internal electrical components and circuitry of the optical sensor module 100. The housing cap 125 may comprise plastic, ceramic, or other protective material. The housing cap 125, for example, may be a plastic cap, and/or a molded cap formed of a molding material, such as a resin, a Liquid Crystal Polymer (LCP), Nylon, or another engineering plastic. In some embodiments, the housing cap 125 may be formed using an injection method/technique.

The housing cap 125 is attached to the substrate 102 to form a housing (e.g., an internal compartment) to protect the internal electrical components (and/or other components) of the optical sensor module 100. The housing cap 125, for example, may be adapted to at least partially enclose, or cover, the components which are mounted on the substrate 102 such as the optical radiation-emitting device 110, the optical radiation receiver 120, the reference sensor 106, the laser driver 144, photodiode 146, and/or the photodiode 146.

Although depicted in FIG. 1 and FIG. 2 as attached to the substrate 102, in some embodiments, the housing cap 125 may be attached to a receiving element configured to receive and attach the housing cap 125. In some embodiments, the housing cap 125 includes conductive pins and/or conductive pads to provide electrical connection to internal electrical components of the optical sensor module 100, as described further herein.

As depicted in FIG. 2 the housing cap 125 defines a transmission opening 130 and a receiving opening 140. In particular, the housing cap 125 has a top portion 126 that defines a transmission opening 130 and a receiving opening 140. The transmission opening 130 and the receiving opening 140 may have any suitable shape (e.g., rectangular, square, circular, or the like).

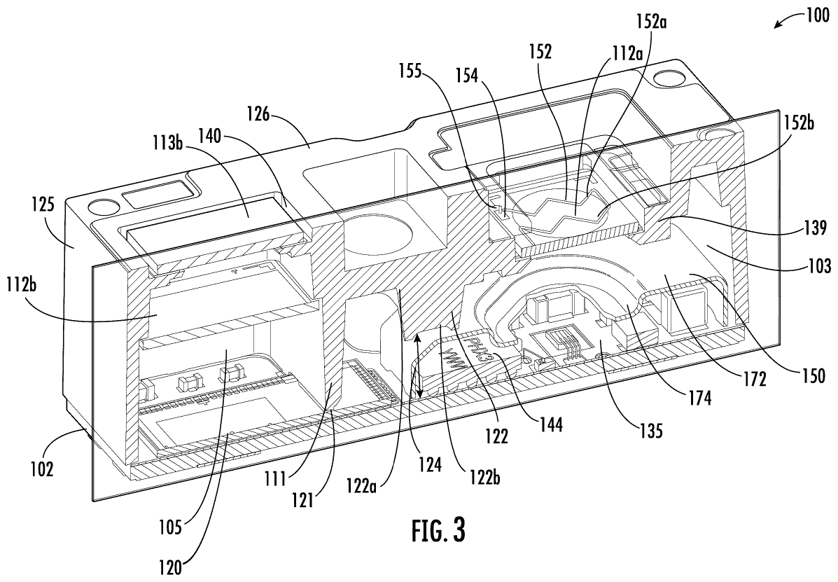

FIG. 3 depicts a cross section view of an optical sensor module in accordance with an example embodiment of the present disclosure. As depicted in FIG. 3, the housing cap 125 includes a barrier wall 111 extending downwardly from the top portion 126 of the housing cap 125 towards the top surface 102a of the substrate 102. In various embodiments, the distal end of the barrier wall 111 is attached to the IC device 127 and the top surface 102a of the substrate 102 using adhesive material such as, for example, opaque glue 121. The barrier wall 111 divides the optical sensor module 100 into two cavities, a transmission cavity 103 and a receiving cavity 105, and forms an optical isolator for substantially preventing the internal propagation of light beams between the optical radiation-emitting device 110 and the optical radiation receiver 120. For example, as depicted in FIG. 3, the distal end of the barrier wall 111 may be attached to the IC device 127 and the substrate 102 such that the transmission cavity 103 and the receiving cavity 105 are optically separated from each other, including optically separating the optical radiation receiver 120 and the reference sensor 106.

The barrier wall 111 is any protrusion, appendage, or other structure that is a part of or attached to the housing cap 125 and configured to abut to the substrate 102, or other surface, to divide the internal compartment of the optical sensor module 100 into the transmission cavity 103 and the receiving cavity 105. In some embodiments, the housing cap 125 may attach to the substrate or other surface of the barrier wall 111. The barrier wall 111 may comprise plastic, ceramic, or other protective material. In some embodiments, the barrier wall 111 and the housing cap 125 may form a single, continuous structure. For example, the barrier wall 111 may be formed with the housing cap 125 as part of an injection molding process. In some embodiments, the injection molding material may comprise Nylon, Liquid Crystal Polymer (LCP), and/or the like.

The barrier wall 111 forms an optically impenetrable barrier between the transmission cavity 103 and the receiving cavity 105. An optically impenetrable barrier prevents light or other optical radiation from traversing from one side of the barrier wall 111 to the other. For example, optical radiation transmitted from the optical radiation-emitting device 110 is unable to internally traverse the barrier wall 111 and enter into the receiving cavity 105.

The transmission cavity 103 includes the transmission opening 130 above the optical radiation-emitting device 110. The optical radiation-emitting device 110, the reference sensor 106, laser driver 144, and photodiode 146 may be located in the transmission cavity 103. The receiving cavity 105 includes the receiving opening 140 above the optical radiation receiver 120.

As described above, the optical radiation-emitting device 110 may comprise a first optical radiation source 110a and a second optical radiation source 110b and may be configured to output optical radiation. The optical radiation-emitting device 110 and the transmission opening 130 are aligned such that an optical radiation path is created for optical radiation generated/emitted by the optical radiation-emitting device 110. In various embodiments, one or more transmission lens 112a is disposed between the transmission opening 130 and the optical radiation-emitting device 110 for directing optical radiation emitted by the optical radiation-emitting device 110 to a target object. For example, a transmission lens 112a may be an optical lens, where the optical radiation emitted by the optical radiation-emitting device 110 is directed through the transmission lens 112a toward the target object. In this regard, the transmission opening 130 is any hole, slit, aperture, or other opening aligned with the optical radiation-emitting device 110 to facilitate the transmission of optical radiation toward a target object. Further, the transmission opening 130 may include optical features such as optical lenses (e.g., transmission lens 112a), structures, beam shaping elements or light diffusers, or other features to direct optical radiation emitted by the optical radiation-emitting device toward a target object and/or various portions of a target object.

In various embodiments, the optical sensor module 100 includes a transmission lens 112a positioned in the transmission opening 130 and within the transmission cavity 103. As depicted in FIG. 2 and FIG. 3, the transmission lens 112a is positioned above the optical radiation-emitting device (e.g., above the one or more optical radiation sources 110a, 110b thereof). The transmission lens 112a preferably covers the transmission opening 130 and is preferably attached to the housing cap 125. For example, the transmission lens 112a may sit on a mounting 139 which is formed within the transmission opening 130. In some embodiments, the transmission lens 112a may comprise two optical surfaces which may be two beam shapers, a first beam shaper located over the first optical radiation source 110a, and a second beam shaper located over the second optical radiation source 110b. In various embodiments, the transmission lens 112a comprise glass. Transmission opening (e.g., transmission aperture) such as those disclosed in U.S. patent application Ser. No. 18/432,693 filed on Feb. 5, 2024. The foregoing patent application is herein incorporated by reference.

The transmission lens 112a includes at least one conductive trace 152 (e.g., electrically conductive trace), which may be embedded in the transmission lens 112a. The transmission lens 112a may further include one or more conductive pads 154 (e.g., bond pads, solder pads) coupled to the conductive trace 152. For example, the transmission lens 112a may include two conductive pads, each at an end of the conductive trace 152. The conductive trace material may be copper (Cu), aluminum (Al), tungsten (W), titanium (Ti), gold (Au), indium-tin oxide (ITO) or another metal or metal alloy. In some example implementations, the thickness of the conductive trace(s) 152 may be about 25 micrometers without being limited to these values. In some example implementations, the conductive trace(s) 152 may have a width less than 1 micrometer and/or a thickness less than 100 nanometers, without being limited to these values. It would be appreciated that the conductive trace(s) 152 may have a width and/or thickness that is greater than or less than the examples provided above (e.g., thickness greater than 25 micrometers or less than 25 micrometers, width greater than 1 micrometer). In some example implementations, the width and thickness of each conductive trace may be a trade-off between the safety function and the optical transmittivity of the transmission lens 112a. For example, the conductive trace 152 could be wider and/or thicker where the trace is not likely to limit light transmission and could be finer and/or thinner where the trace may limit light transmission. For example, while it may be desirable not to limit transmission from the active area of the transmission lens 112a, there may be some limitation due the resistance created by the electrical circuit. For example, if the conductive trace has a thickness of about 10 micrometer trace (e.g., thinner relative to the 20 micrometer trace thickness example) which more traverses across the transmission lens (e.g., longer trace line), overall trace resistance may be too high for detection purposes.

As depicted in FIG. 3, the conductive trace 152 comprises a first leg 152a and a second leg 152b that are at least partly on the transmission lens 112a. In some embodiments, the transmission lens 112a may comprise two or more active regions. In such embodiments, the conductive trace 152 may comprise a first leg 152a and a second leg 152b that are at least partly on a first active region of the transmission lens 112a, and a third leg 152c and fourth leg 152d that are at least partly on the second optical region. In some embodiments, the optical sensor module 100 may comprise a second transmission lens. In such embodiments, the conductive trace 152 may comprise a third leg 152c and a fourth leg 152d that are at least partly on a second transmissions lens.

As illustrated in FIG. 2 and FIG. 3, the first leg 152a and the second leg 152b of the conductive trace are parallel zigzag legs. That is, in various embodiments, each leg comprises at least three substantially straight segments that are angled back and forth in a zigzag manner. In the illustrated embodiment, each leg comprises four substantially straight segments that are angled back and forth in a zigzag manner. In the illustrated embodiment, the first leg 152a comprises a substantially straight first segment, a substantially straight second segment, a substantially straight third segment, and a substantially straight fourth segment, and the second leg 152b comprises a substantially straight first segment, a substantially straight second segment, a substantially straight third segment, and a substantially straight fourth segment. The regularity and the parallel spacing of the zigzag legs provide a placement of the conductive trace that provides good protective coverage for detecting damage to the active region while keeping the transmission loss due to blockage of the light by the conductive trace low.

The optical sensor module 100 further comprises two conductive leads 134, assembled to the housing cap 125. The conductive leads 134 are configured and positioned in order to electrically couple the conductive trace(s) 152 of the transmission lens 112a to the substrate 102. Conductive leads 134 are for example lead frames. In this regard, a conductive trace 152 of the transmission lens 112a may be electrically connected via bond wire to a conductive lead (e.g., lead frame), which in turn is electrically connected to a component on the substrate 102 that monitors electrical characteristics (e.g., resistance) of the conductive trace 152. In various embodiments, the component that monitors an electrical characteristic of the conductive trace is driver, such as a laser driver 144.

Each conductive lead 134 may be a single conductive piece, for example a single metallic piece. Each conductive lead 134 may be inserted into recesses, or channels, formed in the housing cap 125. In some embodiments, instead of being inserted into channels in the housing cap 125, the conductive leads 134 may be conductive layers formed on surfaces of the housing cap 125. The conductive layers may be coated, or plated, on the housing cap 125, for example formed using a laser direct structuring (LDS) technique.

In some embodiments, the conductive leads 134 may be overmolded during an injection molding operation for forming the housing cap 125. The conductive leads are then overmolded in the housing cap 125. Each conductive lead 134 comprises a first end 134a coupled, for example connected, to the substrate 102 through one of the conductive pads 101 on the substrate 102, and a second end 134b coupled, for example connected, to the conductive trace 152 through one of the conductive pads on the transmission lens 112a (e.g., that is coupled to the conductive trace 152 as described above). The first end 134a of each conductive lead 134 may be coupled to one of the conductive pads 101 on the substrate 102 by a conductive adhesive material, for example a conductive tape, paste or glue, or a conductive solder.

The second end 134b of each conductive lead 134 may be coupled to the conductive pads on the transmission lens 112a (e.g., that coupled to the conductive trace 152 as described above) by a conductive wire 155 formed by wire bonding, which may be called a “wire bond” or “bond wire”. Therefore, the conductive leads 134 are coupled to the conductive trace 152, through the conductive pads on the transmission lens 112a (e.g., that is coupled to that is conductive trace 152 as described above), using the wire bonds. The conductive wires 155 are preferably flexible enough, for example to absorb the dimensional changes between the transmission lens 112a, the housing cap 125 and the conductive leads 134, which may be due to different coefficients of thermal expansion (CTE). A function of the conductive wires may be to provide a flexible connection between the conductive leads 134 and the housing cap 125, in particular between the conductive leads 134 and the conductive pads on the transmission lens 112a.

The material of the conductive wires 155 may be gold, copper, aluminum, silver, or even a tin alloy. By using conductive wires formed by wire bonding, the connection may be mechanically and electrically stable and withstand CTE difference, the transmission lens 112a may advantageously be close to the transmission opening of the housing cap 125.

While, two conductive leads and two conductive wires are described, it would be appreciated that the optical sensor module 100 may comprise one conductive lead and one conductive wire formed by wire bonding and coupling the conductive trace to the conductive lead. The optical sensor module may also comprise more than two conductive leads and more than two conductive wires. In some embodiments, each conductive lead may be replaced by a connecting flex.

Each conductive wire 155, and/or the bonding of each conductive wire 155, may function as a fuse in that the conductive wire, and/or the bonding of each conductive wire, may be designed to break an electrical connection in order to provide a protection mechanism. The bonding of the conductive wire corresponds to its connection, when formed by wire bonding, with a conductive trace 152 and/or a conductive lead 134. In particular, the conductive wire, and/or the bonding of each conductive wire, may be arranged to be broken if the transmission lens 112a is removed or otherwise becomes detached from the housing cap 125. In particular, the fuse is configured to break in the event of a mechanical force caused by the detachment of the transmission lens 112a.

The conductive trace(s) 152 may be used as a protection against EMI through the transmission opening 130 of the housing cap 125, for example, by providing EMI reflection in the transmission opening 130. Conductive traces on a lens, electrical connection of lead frames to conductive traces such as those disclosed in U.S. patent application Ser. No. 18/746,712 filed on Jun. 18, 2024 and French Patent Application No. 2311572 filed on Oct. 25, 2023. The foregoing patent applications are hereby incorporated by reference.

In various embodiments, the target object may reflect at least a portion of the optical radiation as reflected optical radiation back toward the optical sensor module 100. The reflected optical radiation is received through the receiving opening 140 and collected by the optical radiation receiver 120.

The receiving opening 140 includes a receiver filter 113b and a receiver lens 112b configured to direct the reflected optical radiation into the receiving cavity 105 and toward the optical radiation receiver 120. The optical radiation received at the optical radiation receiver 120 is configured to pass through the receiver lens 112b configured to direct the reflected optical radiation into the receiving cavity 105. The receiver lens 112b, for example, may be an optical lens configured to distort the optical radiation, filter certain wavelengths of the optical radiation, or otherwise alter or direct the received optical radiation.

The receiver filter 113b is any device configured to selectively transmit, reflect, or block light of different wavelengths. The receiver filter 113b may be configured to prevent ambient light from reaching the optical radiation receiver 120 (e.g., the SPAD thereof). Such receiver filter may comprise glass, plastic, or similar transparent material. A receiver filter may include dyes of coating to reflect, transmit, or absorb incoming light depending on the wavelength. The receiver filter 113b is positioned in the receiving opening 140, or between the receiving opening 140 and the optical radiation receiver 120, and adapted to transmit the optical radiation (e.g., light signals) reflected towards the optical radiation receiver 120. In various embodiments, the receiver filter 113b may cover the receiving opening 140 and/or may be attached to the housing cap 125. For example, the filter 113b may be positioned inside the housing cap 125. In some embodiments, the receiver filter is assembled above the receiver lens 112b using adhesive such as glue and/or the like. In some embodiments, the receiver filter 113b may be mounted outside the housing cap 125. In various embodiments and as shown in FIG. 2, the filter 113b is positioned above the receiver lens 112b.

The operating environment of the optical sensor may include optical noise such as ambient light. For example, a portion of the optical noise may enter into a transmission cavity 103 and be captured by the reference sensor 106. Optical noise is any light or other optical radiation in the operating environment of the optical sensor module 100 that may enter into the transmission cavity 103 through a transmission opening 130 or another opening in the housing cap 125. Optical noise may comprise ambient light and/or light from other optical radiation sources. A portion of the optical noise may enter through the transmission opening 130 and interact with the reference sensor 106. Optical noise received at the reference sensor 106 affects the performance of the optical sensor module 100.

One technique used to prevent optical noise from entering the transmission cavity 103 is to place a transmission filter over at least a portion of the transmission opening 130. A transmission filter may be designed to block at least a portion of the light spectrum from entering the transmission cavity 103. However, a transmission filter may allow certain wavelengths of optical noise to enter into the transmission cavity 103. In addition, transmission filters add to the overall cost of the optical sensor module 100. Further, transmission filters may be difficult to align and attach to the transmission opening 130. Transmission filters may also fail. For example, transmission filters may detach, allowing all optical noise to enter the transmission cavity 103. A portion of optical noise in the transmission cavity 103 may be especially prevalent in an instance in which a transmission filter is detached or removed.

As further depicted in FIG. 3, the housing cap 125 includes attenuation wall 122 having an attached end 122a and distal end 122b extending from the top portion 126 of the housing cap 125 toward the substrate 102. The attenuation wall 122 forms an attenuation gap 124 between the distal end 122b of the attenuation wall 122 and a top surface of an EMI shield 150 (described further below) or top surface 102a of the substrate 102, allowing a portion of the optical radiation to pass to the reference sensor 106 while blocking optical noise.

An attenuation gap 124 is any opening, aperture, slit, hole, or other gap in the attenuation wall 122 enabling the passage of optical radiation from one side of the attenuation wall 122 to the other.

The top portion 126 of the housing cap 125 defines the transmission opening 130 and receiving opening 140 of the optical sensor module 100. Thus, the top portion 126 of the housing cap 125 comprises the portion of the housing cap 125 at which the optical radiation is directed and the reflected optical radiation returns. The top portion 126 allows the flow of optical radiation into and out of the optical sensor module 100 while generally blocking optical noise from the operating environment from entering into the transmission cavity 103 and receiving cavity 105. In addition, the top portion 126 of the housing cap 125, along with the outer walls of the housing cap 125 provides protection to the internal electrical components of the optical sensor module.

As depicted in FIG. 3, the housing cap 125 includes an attenuation wall 122 extending from the top portion 126 of the housing cap 125 into the transmission cavity 103 toward the top surface 102a of the substrate 102. The attenuation wall 122 is any barrier, wall, or obstruction defined by the housing cap 125 and positioned within the transmission cavity 103 between the transmission opening 130 aligned with the optical radiation-emitting device 110 and the reference sensor 106. The attenuation wall 122 comprises any optically impenetrable material. In some embodiments, the attenuation wall 122 comprises plastic, ceramic, or other material comprising the housing cap 125.

In some embodiments, the attenuation wall 122, the barrier wall 111, the top portion 126, and the housing cap 125 may form a single, continuous structure. For example, the attenuation wall 122 may be formed with the housing cap 125 as part of an injection molding process. Alternatively, in some embodiments, the attenuation wall 122 may comprise a separate material from the housing cap 125 and/or be separately attached to the top portion 126 of the housing cap 125.

As depicted in FIG. 3, the attenuation wall 122 includes an attached end 122a and a distal end 122b. The attached end 122a connects the attenuation wall 122 to the top portion 126 of the housing cap 125. The distal end 122b extends into the transmission cavity 103 to form the attenuation gap 124. As depicted in FIG. 3, the attenuation gap 124 is formed between the distal end 122b of the attenuation wall 122 and the top surface of an EMI shield 150 (described further below) of the optical sensor module 100, allowing a portion of the optical radiation to pass to the reference sensor 106 while blocking optical noise. Attenuation walls such as those disclosed in U.S. patent application Ser. No. 18/417,190 filed on Jan. 19, 2024. The foregoing patent application is herein incorporated by reference.

As depicted in FIGS. 1-3, an EMI shield 150 is attached to the substrate 102 or other attaching surface within the optical sensor module 100 and positioned to enclose one or more electrical components, particularly components sensitive to EMI. In some embodiments, one or more electrical components of the optical sensor module 100 may be sensitive to EMI or otherwise susceptible to disruption from external electromagnetic emissions. For example, an electrical component may be configured to transmit and receive data. External electromagnetic emissions may corrupt data during processing or transmission or may even cause the electrical component to cease operation. An EMI shield 150 may be positioned to at least partially cover one or more components of the optical sensor module 100 that is susceptible to disruption from external electromagnetic emissions (e.g., sensitive to EMI). In some embodiments, an electrical component may be identified as a source emitter of electromagnetic radiation. An EMI shield 150 may be positioned to envelope at least partially cover such an electrical component to prevent the internal electromagnetic emissions from exiting the EMI shield 150.

In various embodiments, the EMI shield 150 is shaped and dimensioned to surround and at least partially cover one or more components of the optical sensor module 100, as described above. In particular, the EMI shield may be shaped and dimensioned to at least partially cover the laser driver 144 configured for controlling the optical radiation-emitting device. Further, the EMI shield 150 may be shaped and dimensioned to at least partially cover the optical radiation-emitting device 110.

The EMI shield 150 defines an aperture 135 that provides an opening through which optical radiation emitted from the optical radiation-emitting device (e.g., one or more optical radiation sources such as the first optical radiation source 110a and the second optical radiation source 110b) pass before exiting the optical sensor module 100. In particular, in various embodiments, the EMI shield defines an aperture dimensioned and/or configured such that optical radiation emitted from the optical radiation-emitting device (e.g., one or more optical radiation sources such as the first optical radiation source 110a and the second optical radiation source 110b) may to pass through without obstruction (while preventing EMI from passing through) and such that the field of view (FOV) of the photodiode 146 is not obstructed. In this regard, in various embodiments, the aperture 135 of the EMI shield 150 is configured taking into consideration optical radiation emitted from the first optical radiation source 110a and the second optical radiation source 110b and taking into consideration the field of view (FOV) of the photodiode 146. In various embodiments, the EMI shield 150 is formed or otherwise made from metal such as, but not limited to, copper, brass, steel, nickel, nickel silver, silver, beryllium copper, or stainless steel (e.g., SUS 304, SUS 406, or the like) or any suitable electrically conductive material. The EMI shield 150, for example, may be a metal shield. EMI shielding and metal shields such as those disclosed in French Patent Application No. 2311593 filed on Oct. 25, 2023. The foregoing patent application is herein incorporated by reference. In various embodiments, the example transmission lens 112a is positioned relative to the optical radiation-emitting device such that the optical radiation generated by the optical radiation-emitting device passes through the transmission lens. In various embodiments, the transmission lens 112a is positioned based on the position of the optical radiation-emitting device (e.g., one or more optical radiation sources such as the first optical radiation source 110a and the second optical radiation source 110b).

In various embodiments, the EMI shield 150 comprise sidewalls 170, a top wall 172 (e.g., top surface) and defines an interior, wherein one or more components of the optical sensor module 100 are positioned, including the optical radiation-emitting device 110, laser driver 144, photodiode 146, and/or other components of the optical sensor module positioned within transmission cavity 103. In various embodiments, the top wall 172 includes an inner surface 174 surrounding the aperture. In some embodiments, the inner surface 174 is angled. For example, the top wall 172 may comprise inner angled surface. The EMI shield 150, for example, may comprise or is otherwise embodied as a metal can comprising sidewalls 170 and a top surface 172 having an inner angled surface surrounding the aperture 135. In some embodiments, the EMI shield 150 includes an absorber layer located on the internal surface of the top wall 172. The absorber layer comprises a material suitable for absorbing electromagnetic waves, such as EMI absorber materials.

As depicted in FIGS. 1-3, the EMI shield and the aperture 135 thereof are positioned within the transmission cavity 103 and the aperture 135 provides an opening through which optical radiation from the optical radiation-emitting device 110 passes before exiting the optical sensor module 100. In various embodiments, the shapes and/or angles of various surfaces of the aperture 135 help reduce crosstalk by reducing reflections toward the receiving opening 140.

In some embodiments, the EMI shield 150 (e.g., defining an aperture 135) of the optical sensor module 100 is constructed separately from the housing cap 125 and the substrate 102 and is inserted and secured to the substrate 102 during assembly of the optical sensor module 100. In some embodiments, the EMI shield 150 of the optical sensor module 100 is constructed as an integral part of the optical sensor module 100.

In some embodiments, the EMI shield 150 is conductively bonded to the substrate 102. For example, solder or conductive glue may be used to conductively bond the EMI shield 150 to the substrate 102.

The EMI shield 150 may be opaque to optical radiation, such that optical radiation is unable to penetrate or pass through the EMI shield 150. Thus, in various embodiments, the EMI shield 150 is positioned near the distal end 122b of the attenuation wall 122 and form an attenuation gap 124 through which a portion of the optical radiation from the optical radiation-emitting device 110 may pass while blocking at least a portion of the optical noise entering the transmission cavity 103 through the transmission opening 130.

The attenuation gap 124 formed by the attenuation wall 122 and the EMI shield 150 may vary based on the size and relative positions of the optical radiation-emitting device 110, the reference sensor 106, the attenuation wall 122, the transmission opening 130, and other components of the optical sensor module 100. For example, the attenuation wall depth (e.g., the distance from the optical radiation-emitting device side of the attenuation wall 122 to the reference sensor side of the attenuation wall 122), attenuation wall length (e.g., the distance from the attached end 122a of the attenuation wall 122 to distal end 122b of the attenuation wall 122), attenuation wall distance (e.g. the distance from the optical radiation-emitting device 110 to the center of the attenuation wall 122), reference sensor distance (e.g., the distance from the reference sensor 106 to the optical radiation-emitting device 110), transmission lens distance (e.g., e.g., the distance from the optical radiation-emitting device 110 to the transmission lens 112a), and transmission opening diameter (e.g., the diameter of the transmission opening 130) may affect the size and position of the attenuation gap 124.

As described above, the attenuation gap 124 is the gap between distal end 122b of the attenuation wall 122 and the internal structure (e.g., EMI shield 150), or other surface most proximate distal end 122b of the attenuation wall 122. The attenuation gap 124 may be measured based on the widest portion of the attenuation gap 124, the narrowest portion of the attenuation gap 124, the average distance of the attenuation gap 124, or other similar measuring mechanism.

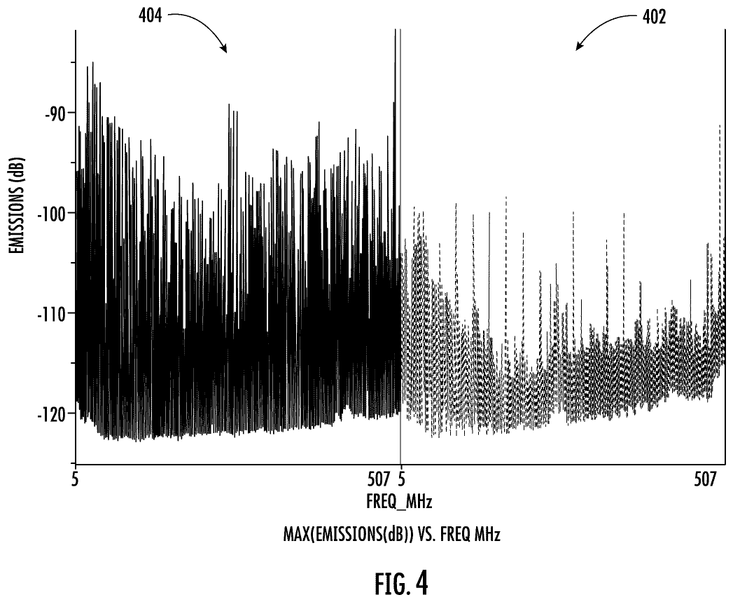

FIG. 4 depicts electromagnetic emission plots comparing electromagnetic emissions 402 of an example optical sensor module having an EMI shield in accordance with an example embodiment of the present disclosure with electromagnetic emissions 404 of an optical sensor module without an EMI shield. The x-axis of the emissions plots represents frequency in MHZ and the y-axis of the electromagnetic emissions plots represents electromagnetic emissions in db. As depicted in FIG. 4, the example optical sensor module 100 having an EMI shield showed about 10 db improvement from 5 MHz to 500 MHz relative to an optical sensor module without an EMI shield. Specifically, the electromagnetic emissions between 5 MHz and 500 MHz for the optical sensor module with an EMI shield is about 10 db lower relative to the electromagnetic emissions between 5 MHz to 500 MHz for the optical sensor module without an EMI shield.

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. The disclosed embodiments relate primarily to optical sensors, however, one skilled in the art may recognize that such principles may be applied to any sensors and devices. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of having an optical radiation source and optical radiation receiver in which reduction of crosstalk is desirable, such as time of flight sensors, LiDAR sensors or any laser ranging application, and can cover any form of electronic device that utilizes an optical source to determine a proximity and/or range of a target object. For example, mobile devices, such as phone, tablets, and laptops; wearable electronic devices such as watches and ear buds; consumer electronics such as robotic vacuums and projection systems; industrial electronics such as unmanned aerial vehicles, robotics, and so forth.

Within the appended claims, unless the specific term “means for” or “step for” is used within a given claim, it is not intended that the claim be interpreted under 35 U.S.C. 112, paragraph 6.

What is claimed is:

1. An optical sensor module comprising:
an optical radiation-emitting device configured to generate optical radiation directed at a target object;
a reference sensor positioned to receive a portion of the optical radiation;
an optical radiation receiver positioned to receive reflected optical radiation reflected off the target object;
an electromagnetic interference shield defining an interior, wherein the optical radiation-emitting device is positioned within the interior, and wherein the electromagnetic interference shield comprises a top surface defining an aperture positioned such that the optical radiation generated by the optical radiation-emitting device passes through the aperture; and
a housing cap comprising:
a barrier wall positioned such that the housing cap defines a transmission cavity and a receiving cavity, wherein the optical radiation-emitting device and the reference sensor are positioned within the transmission cavity, and wherein the optical radiation receiver is positioned within the receiving cavity; and
an attenuation wall positioned between the reference sensor and the optical radiation receiver.

2. The optical sensor module of claim 1, wherein the barrier wall creates an impenetrable barrier between the transmission cavity and the receiving cavity.

3. The optical sensor module of claim 1, wherein the attenuation wall is positioned over the electromagnetic interference shield such that the attenuation wall and the electromagnetic interference shield define an attenuation gap through which the portion of the optical radiation passes to the reference sensor.

4. The optical sensor module of claim 1, further comprising:
an integrated circuit device, wherein the integrated circuit device comprises the optical radiation receiver and the reference sensor, and wherein a distal end of the barrier wall is attached to the integrated circuit device.

5. The optical sensor module of claim 1, further comprising:
a receiver lens positioned within the receiving cavity and above the optical radiation receiver.

6. The optical sensor module of claim 5, further comprising:
a receiver filter positioned within the receiving cavity and above the receiver lens.

7. The optical sensor module of claim 1, further comprising:
a substrate, wherein the optical radiation-emitting device, the reference sensor, the optical radiation receiver, and the electromagnetic interference shield are disposed on the substrate and electrically connected to the substrate.

8. The optical sensor module of claim 7, further comprising:
at least one conductive pad disposed on the substrate and electrically connected to ground, wherein the electromagnetic interference shield is electrically connected to the substrate via the at least one conductive pad.

9. The optical sensor module of claim 8, further comprising:
a transmission lens positioned relative to the optical radiation-emitting device such that the optical radiation generated by the optical radiation-emitting device passes through the transmission lens.

10. The optical sensor module of claim 9, wherein the transmission lens comprises a conductive trace.

11. The optical sensor module of claim 10, further comprising:
at least one conductive lead frame positioned within the interior of the housing cap and electrically connected to the substrate; and
at least one conductive wire formed by wire bonding, the at least one conductive wire electrically connecting the at least one conductive lead frame to the conductive trace.

12. The optical sensor module of claim 1, wherein the electromagnetic interference shield comprises a metal can.

13. The optical sensor module of claim 1, wherein the housing cap further comprises:
a top portion defining a transmission opening positioned over the optical radiation-emitting device such that the optical radiation generated by the optical radiation-emitting device passes through the transmission opening to the target object.

14. The optical sensor module of claim 13, wherein the top portion of the housing cap further defines a receiving opening positioned over the optical radiation receiver, such that the reflected optical radiation passes through the transmission opening to the optical radiation receiver.

15. The optical sensor module of claim 13, wherein the top portion and the attenuation wall comprise a single, continuous structure.

16. The optical sensor module of claim 13, wherein the top portion and the barrier wall comprise a single, continuous structure.

17. The optical sensor module of claim 1, wherein the optical radiation-emitting device comprises at least one optical radiation source.

18. The optical sensor module of claim 1, wherein the optical radiation receiver comprises a first single photon avalanche diode and the reference sensor comprises a second single photon avalanche diode.

19. The optical sensor module of claim 1, wherein the top surface of the electromagnetic interference shield comprises an inner angled surface surrounding the aperture.

20. The optical sensor module of claim 1, further comprising:
a driver configured for controlling the optical radiation-emitting device; and
a photodiode configured to monitor the optical radiation-emitting device, wherein the driver and the photodiode are positioned within the interior defined by the electromagnetic interference shield.
